(19) United States
(12) Patent Application Publication
(10) Pub. No.: US 2008/0057640 A1
(43) Pub. Date: Mar. 6, 2008

(54) METHOD FOR FABRICATING FIRST ELECTRODE OF CAPACITOR

(75) Inventors: LI-CHENG TENG, TAICHUNG COUNTY (TW); CHUN-WEI YU, TAIPEI COUNTY (TW); CHUN-CHONG FU, CHANGHUA COUNTY (TW); YUAN-MING CHANG, HSINCHU COUNTY (TW)

Correspondence Address: J C PATENTS, INC., 4 VENTURE, SUITE 250, IRVINE, CA, 92618, US

(73) Assignee: PROMOS TECHNOLOGIES INC., HSINCHU COUNTY (TW)

(21) Appl. No.: 11/559,062

(22) Filed: Nov. 13, 2006

(30) Foreign Application Priority Data
Sep. 5, 2006 (TW) 95132699

(51) Int. Cl. H01L 21/8244

(52) U.S. Cl. 438/238

(57) ABSTRACT

A method for fabricating a first electrode of a capacitor is described. A substrate comprising an insulating layer formed thereon is provided. The insulating layer has an opening. A silicon layer is formed on the insulating layer. The silicon layer is transformed to a hemispherical grain layer. An etching process is performed to remove a portion of the hemispherical grain layer outside the opening.

### CROSS-REFERENCE TO RELATED APPLICATION

This application claims the priority benefit of Taiwan application serial no. 95132699, filed Sep. 5, 2006. All disclosure of the Taiwan application is incorporated herein by reference.

### BACKGROUND OF THE INVENTION

1. Field of the Invention

The present invention relates to a method for fabricating a capacitor, and more particularly, to a method for fabricating a first electrode of a capacitor.

2. Description of Related Art

Semiconductor integrated circuits normally require capacitors, in particular, memory devices need capacitors so that each memory device is able to store binary data according to the degree of bias in the capacitor. For a memory device such as a dynamic random access memory (DRAM), the reading/writing actions of the DRAM are achieved through a transfer field effect transistor (TFET). The source of the transfer field effect transistor is electrically coupled to the bit line, the drain is electrically coupled to the capacitor, and the gate is electrically coupled to the word line. The storage of electric charges in the capacitor is the basic memory characteristic of the DRAM.

The capacity of a capacitor for storing electric charges depends on its capacitance. In general, the capacitance of the capacitor depends on the area of the storage electrodes, the reliability of insulating dielectric layer between the top electrode and the first electrode and the dielectric constant of the dielectric material.

One conventional method of increasing the capacitance of a capacitor includes using a hemispherical grain layer as the first electrode of the capacitor.

FIGS. 1A through 1C are schematic cross-sectional views showing the steps in a conventional process for fabricating a first electrode of a capacitor.

First, as shown in FIG. 1A, a substrate 100 is provided. The substrate 100 has an insulating layer 102 already formed thereon. Furthermore, the insulating layer 102 has an opening 104. Then, an amorphous silicon layer 106 is formed on the insulating layer 102. After that, a photoresist layer 108 is formed inside the opening 104.

Next, as shown in FIG. 1B, a dry etching process is performed using the photoresist layer 108 as a mask to remove a portion of the amorphous silicon layer 106 outside the opening 104. Next, plasma is used to remove the photoresist layer 108.

Subsequently, as shown in FIG. 1C, a cleaning process is performed to clean the surface of the remaining portion of the amorphous silicon layer 106. Next, the remaining portion of the amorphous silicon layer 106 is transformed into a hemispherical grain layer 110.

In the foregoing method of fabricating the first electrode of the capacitor, the photoresist layer 108 may not be completely removed, or the plasma for removing the photoresist layer 108 may damage the surface structure of the amorphous silicon layer 106. As a result, smaller hemispherical grains are formed at the bottom of the opening 104, thereby lowering the surface area of the hemispherical grain layer 110 that serves as the first electrode of the capacitor and reducing the capacitance of the capacitor.

In addition, the conventional method of fabricating the first electrode of the capacitor is rather complicated. Therefore, the inherent problems of having a longer production cycle and a higher production cost for producing the product are hard to remove.

### SUMMARY OF THE INVENTION

Accordingly, at least one objective of the present invention is to provide a method for fabricating a first electrode of a capacitor capable of increasing the capacitance of the capacitor.

At least another objective of the present invention is to provide a method for fabricating a first electrode of a capacitor capable of increasing the production throughput and lowering the production cost.

To achieve these and other advantages and in accordance with the purpose of the invention, as embodied and broadly described herein, the invention provides a method for fabricating a first electrode of a capacitor. First, a substrate comprising an insulating layer formed thereon is provided. The insulating layer has an opening. Next, a silicon layer is formed on the insulating layer. Thereafter, the silicon layer is transformed to a hemispherical grain layer. Next, an etching process is performed to remove a portion of the hemispherical grain layer outside the opening.

According to an embodiment of the present invention, the method of forming the silicon layer includes performing a chemical vapor deposition process.

According to an embodiment of the present invention, the material constituting the silicon layer includes amorphous silicon.

According to an embodiment of the present invention, the method of transforming the silicon layer into a hemispherical grain layer includes performing an ultra-high vacuum chemical vapor deposition process.

According to an embodiment of the present invention, the material constituting the hemispherical grain layer includes polysilicon.

According to an embodiment of the present invention, the etching process includes a dry etching process.

According to an embodiment of the present invention, the opening has an aspect ratio between 25 and 35.

The present invention also provides another method for fabricating a first electrode of a capacitor. First, a substrate comprising an insulating layer formed thereon is provided. The insulating layer has an opening. Next, a silicon layer is formed on the insulating layer. Thereafter, an etching process is performed to remove a portion of the silicon layer outside the opening. Next, the silicon layer is transformed to a hemispherical grain layer.

Accordingly, because a photoresist layer is not required for fabricating the first electrode of the capacitor in the present invention, and therefore the problem of incomplete removal of the photoresist layer or damaging the surface structure of the silicon layer during its exposure to plasma used for removal of the photoresist layer may be effectively avoided. Therefore, it is possible to form dimensionally uniform hemispherical grains inside the opening to effectively increasing the capacitance of the capacitor.

In addition, because a photoresist layer is not required for fabricating the first electrode of the capacitor in the present invention, and therefore there is no need to perform a series of processes including photoresist coating, exposure, development, photoresist removal and silicon layer cleaning. Therefore, the fabricating process is significantly simplified so that the production throughput can be increased and the production cost can be reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1C are schematic cross-sectional views showing the steps in a conventional process for fabricating a first electrode of a capacitor.

FIGS. 2A through 2C are schematic cross-sectional views showing the steps for fabricating a first electrode of a capacitor according to one embodiment of the present invention.

FIGS. 3A through 3C are schematic cross-sectional views showing the steps for fabricating a first electrode of a capacitor according to another embodiment of the present invention.

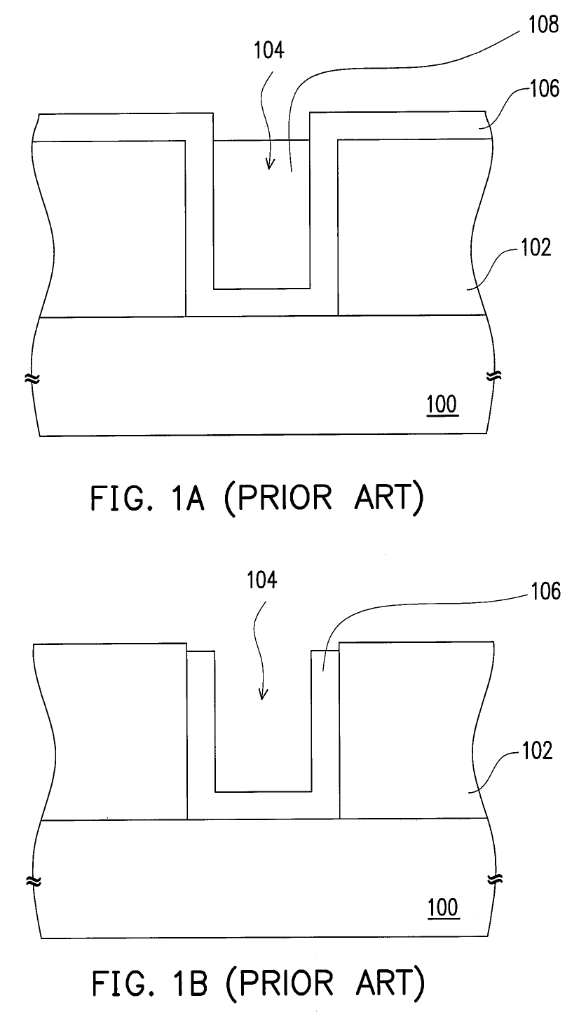

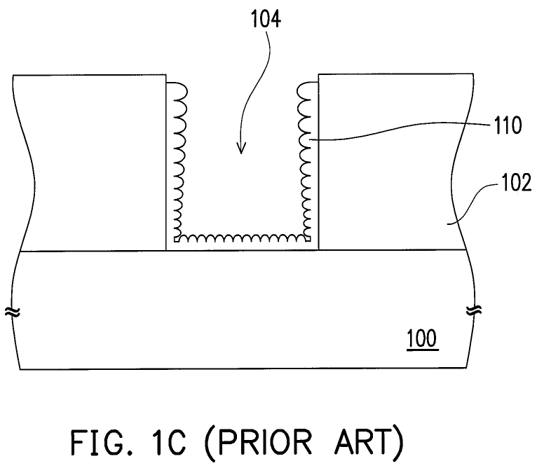

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

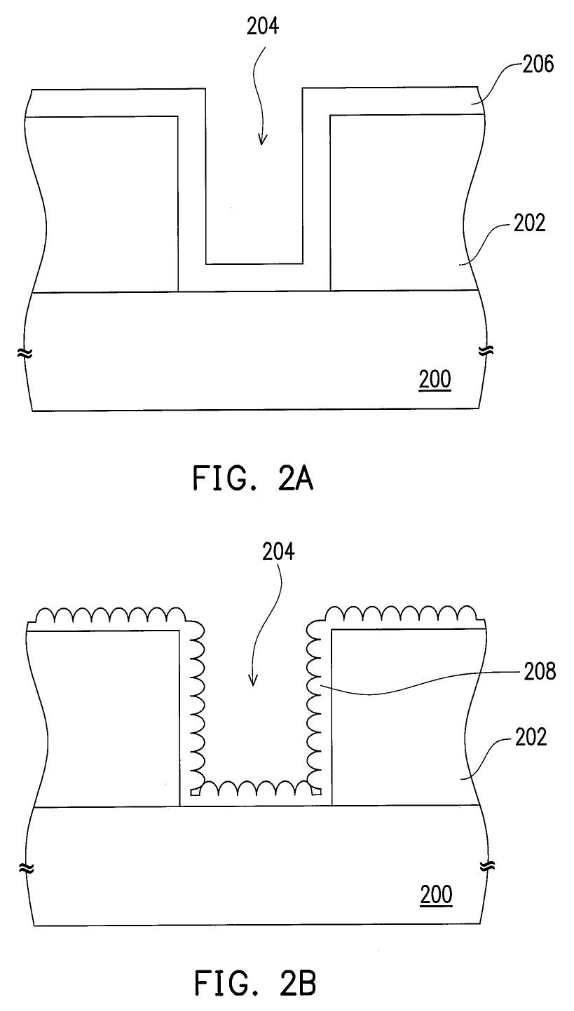

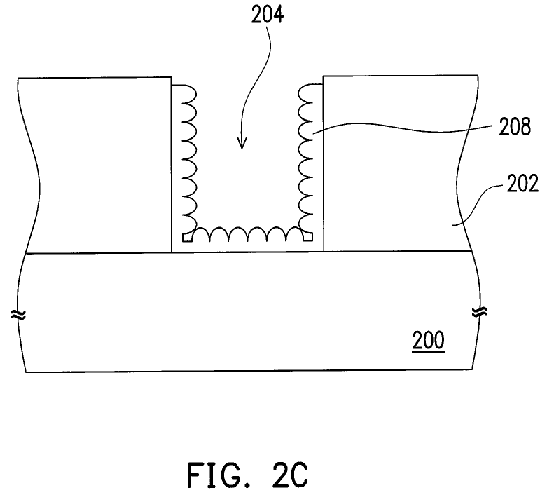

FIGS. 2A through 2C are schematic cross-sectional views showing the steps for fabricating a first electrode of a capacitor according to one embodiment of the present invention.

First, as shown in FIG. 2A, a substrate 200 comprising an insulating layer 202 formed thereon is provided. The insulating layer 202 has an opening 204. The substrate 200 may be comprised of a semiconductor substrate, for example. The insulating layer 202 is a silicon oxide and may be formed, for example, by performing a chemical vapor deposition process. The aspect ratio of the opening 204 is, for example, between 25 and 35. The method of forming the opening 204 includes, for example, performing a patterning process on the insulating layer 202.

Next, a silicon layer 206 is formed on the insulating layer 202. The silicon layer 206 is an amorphous silicon layer formed, for example, by performing a chemical vapor deposition process.

Next, as shown in FIG. 2B, the silicon layer 206 is transformed to a hemispherical grain layer 208. The hemispherical grain layer 208 is fabricated from polysilicon, for example. The method of transforming the silicon layer 206 to the hemispherical grain layer 208 includes, for example, performing an ultra-high vacuum chemical vapor deposition. For example, if the silicon layer 206 is an amorphous silicon layer, the material constituting the silicon layer 206 will transform from amorphous silicon to polysilicon when the ultra-high vacuum chemical vapor deposition process is used to form the hemispherical grain layer 208.

Thereafter, as shown in FIG. 2C, an etching process is performed to remove a portion of the hemispherical grain layer 208 outside the opening 204. The etching process includes, for example, a dry etching process. After the etching process is performed, the remaining hemispherical grain layer 208 serves as the first electrode of the capacitor.

It should be noted that the etching process used for removing a portion of the hemispherical grain layer 208 outside the opening 204 would not remove the remaining portion of the hemispherical grain layer 208 inside the opening 204 due to the high aspect ratio of the opening 204. The process of etching the hemispherical grain layer 208 outside the opening 204 mainly utilizes the difference in selectivity and the micro-loading effect.

Moreover, an over-etching process can be selectively performed to ensure a complete removal of the portion of the hemispherical grain layer 208 outside the opening 204. During the over-etching process, a portion of the hemispherical grain layer 208 near the top of the opening 204 may be removed.

Because a photoresist layer serving as an etching mask is not required for fabricating the first electrode of the capacitor, the problem of incomplete removal of the photoresist layer or damage of the surface structure of the silicon layer 206 due to its exposure to the plasma used for removing the photoresist layer as in the case of the prior art may be effectively eliminated. Therefore, it is possible to form a dimensionally uniform hemispherical grain layer 208 inside the opening 204 to increase the capacitance of the capacitor.

Furthermore, because a photoresist layer is not required for forming the first electrode of the capacitor, therefore there is no need to perform a series of processes including photoresist coating, exposure, development, photoresist removal and cleaning the silicon layer 206 as in the case of conventional art. Accordingly, the production throughput can be increased and the production cost can be reduced.

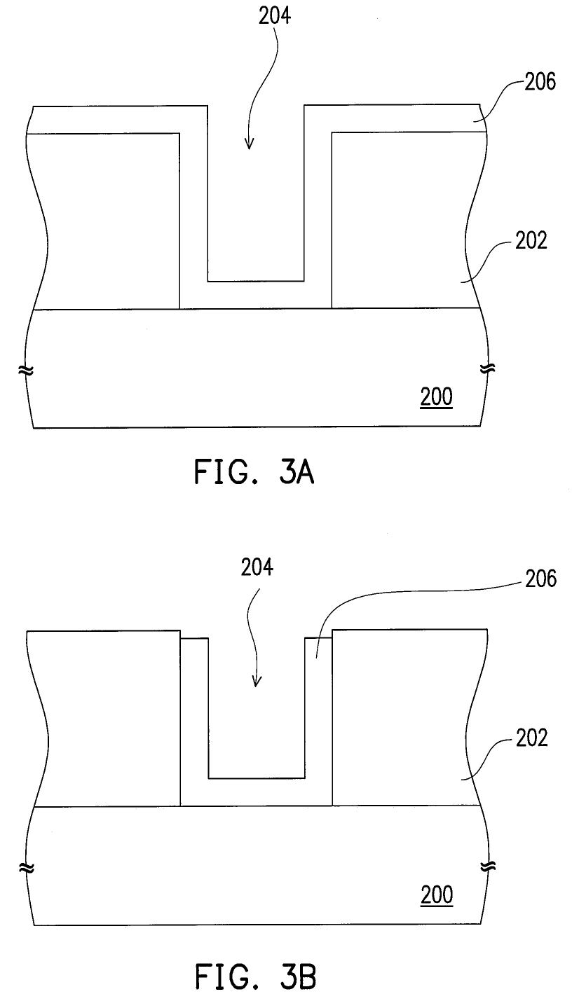

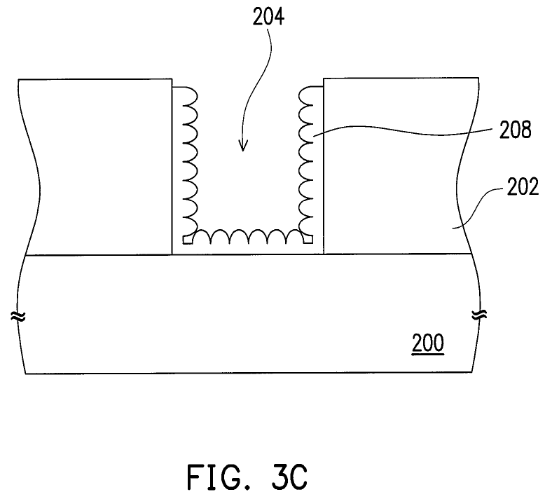

FIGS. 3A through 3C are schematic cross-sectional views showing the steps for fabricating a first electrode of a capacitor according to another embodiment of the present invention.

First, as shown in FIG. 3A, a substrate 200 comprising an insulating layer 202 formed thereon is provided. The insulating layer 202 has an opening 204. The substrate 200 is a semiconductor substrate, for example. The insulating layer 202 is a silicon oxide and may be formed, for example, by performing a chemical vapor deposition process. The aspect ratio of the opening 204 is, for example, between 25 and 35. The method of forming the opening 204 includes, for example, performing a patterning process on the insulating layer 202.

Next, a silicon layer 206 is formed on the insulating layer 202. The silicon layer 206 is an amorphous silicon layer formed, for example, by performing a chemical vapor deposition process.

Next, as shown in FIG. 3B, an etching process is performed to remove a portion of the silicon layer 206 outside the opening 204. The etching process includes, for example, a dry etching process.

It should be noted that the etching process used for removing the portion of the silicon layer 206 outside the opening 204 would not remove the remaining portion of the silicon layer 206 inside the opening 204 due to the high aspect ratio of the opening 204. The process of etching the portion of the silicon layer 206 outside the opening 204 mainly utilizes the difference in selectivity and the micro-loading effect.

In addition, an over-etching process can be selectively performed to ensure a complete removal of the portion of the silicon grain layer 206 outside the opening 204. During the over-etching process, a portion of the silicon layer 206 near the top of the opening 204 may be removed.

Next, as shown in FIG. 3C, the remaining silicon layer 206 is transformed to a hemispherical grain layer 208. The hemispherical grain layer 208 is fabricated from polysilicon, for example. The method of transforming the silicon layer 206 to the hemispherical grain layer 208 includes, for example, performing an ultra-high vacuum chemical vapor deposition. For example, if the silicon layer 206 is an amorphous silicon layer, the material constituting the silicon layer 206 will transform from amorphous silicon to polysilicon when the ultra-high vacuum chemical vapor deposition process is used to form the hemispherical grain layer 208. The hemispherical grain layer 208 serves as the first electrode of the capacitor.

Because a photoresist layer as an etching mask is not required for fabricating the first electrode of the capacitor, the problem of incomplete removal of the photoresist layer or damage on the surface structure of the silicon layer 206 due to its exposure to the plasma used for removing the photoresist layer as in the case of the prior art may be effectively avoided. Therefore, it is possible to form a dimensionally uniform hemispherical grain layer 208 inside the opening 204 to increase the capacitance of the capacitor.

Furthermore, because a photoresist layer is not required for forming the first electrode of the capacitor, and therefore there is no need to perform a series of processes including photoresist coating, exposure, development, photoresist removal and cleaning the silicon layer 206. Hence, the production process can be simplified and the production throughput can be increased and the production cost can be reduced.

In summary, the present invention includes at least the following advantages:

1. Because a photoresist layer is not required for the method of fabricating the first electrode of the capacitor in the present invention, the problem of incomplete removal of the photoresist layer or damage on the surface structure of the silicon layer due to its exposure of the plasma used for removing the photoresist layer may be effectively avoided.

2. The method for fabricating the first electrode of the capacitor in the present invention is capable of increasing the capacitance of the capacitor.

3. The method of fabricating the first electrode of the capacitor in the present invention can effectively simplify the production process.

4. The method of fabricating the first electrode of the capacitor in the present invention can increase the production throughput and lower the production cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a first electrode of a capacitor, comprising:
providing a substrate having an insulating layer formed thereon, wherein the insulating layer has an opening;
forming a silicon layer on the insulating layer;
transforming the silicon layer to a hemispherical grain layer; and
performing an etching process to remove a portion of the hemispherical grain layer outside the opening.

2. The method of claim 1, wherein the step of forming the silicon layer comprises performing a chemical vapor deposition process.

3. The method of claim 1, wherein a material constituting the silicon layer comprises amorphous silicon.

4. The method of claim 1, wherein the step of transforming the silicon layer to the hemispherical grain layer comprises performing an ultra-high vacuum chemical vapor deposition process.

5. The method of claim 1, wherein a material constituting the hemispherical grain layer comprises polysilicon.

6. The method of claim 1, wherein the step of performing the etching process comprises performing a dry etching process.

7. The method of claim 1, wherein the opening has an aspect ratio between 25 and 35.

8. A method for fabricating a first electrode of a capacitor, comprising:
providing a substrate having an insulating layer formed thereon, wherein the insulating layer has an opening;
forming a silicon layer on the insulating layer;
performing an etching process to remove a portion of the silicon layer outside the opening; and
transforming the silicon layer to a hemispherical grain layer.

9. The method of claim 8, wherein the step of forming the silicon layer comprises performing a chemical vapor deposition process.

10. The method of claim 8, wherein a material constituting the silicon layer comprises amorphous silicon.

11. The method of claim 8, wherein the step of transforming the silicon layer to the hemispherical grain layer comprises performing an ultra-high vacuum chemical vapor deposition process.

12. The method of claim 8, wherein a material constituting the hemispherical grain layer comprises polysilicon.

13. The method of claim 8, wherein the step of performing the etching process comprises performing a dry etching process.

14. The method of claim 8, wherein the opening has an aspect ratio between 25 and 35.
